(19) United States
(12) Patent Application Publication
(10) Pub. No.: US 2026/0271335 A1
(43) Pub. Date: Sep. 10, 2026

(54) TRENCH MOSFETS WITH ANGLED TRENCH

(71) Applicant: SEMICONDUCTOR COMPONENTS INDUSTRIES, LLC, Scottsdale, AZ (US)

(72) Inventor: Arash SALEMI, Cary, NC (US)

(73) Assignee: SEMICONDUCTOR COMPONENTS INDUSTRIES, LLC, Scottsdale, AZ (US)

(21) Appl. No.: 19/464,014

(22) Filed: Jan. 29, 2026

Related U.S. Application Data
(60) Provisional application No. 63/768,498, filed on Mar. 7, 2025.

(51) Int. Cl. H10D 30/66; H10D 30/01; H10D 62/10; H10D 62/832; H10D 64/27

(52) U.S. Cl. CPC H10D 30/668; H10D 30/0297; H10D 62/109; H10D 62/111; H10D 62/8325; H10D 64/513

(57) ABSTRACT

A trench MOSFET is disclosed. The trench MOSFET includes a silicon carbide substrate and an epitaxial layer disposed on the substrate, the epitaxial layer having a crystallographic structure with a growth direction that is angularly offset from a surface normal of an upper surface of the epitaxial layer. The trench MOSFET further includes a drift region, a base region, and a source region formed in the epitaxial layer, and a gate formed within a trench. The trench extends through the source region and the base region and has first and second sidewalls that are angularly offset from the surface normal of the upper surface of the epitaxial layer and along respective first and second non-polar crystal planes of the crystallographic structure of the epitaxial layer.

### PRIORITY

This application claims the benefit of provisional patent application No. 63/768,498, filed Mar. 7, 2025, which is hereby incorporated by reference herein in its entirety.

### TECHNICAL FIELD

The disclosure relates generally to semiconductor devices, and particularly to techniques for utilizing an angled trench for a silicon carbide (SiC) metal-oxide-semiconductor field-effect transistor (MOSFET).

### BACKGROUND

Power electronics may be used to control the conversion and distribution of electric power. For example, switching power converters may be used to create a direct current (DC) voltage from an alternating current (AC) voltage by switching current through a magnetic element such as an inductor. Conversely, inverters can be used to convert a DC voltage to an AC voltage. In these and other forms of power electronics, power switches may be used to control the conversion and flow of power through the power-conversion system and to the electronic circuitry to be powered by the device.

Power switches utilized in such power-conversion systems may be required to handle high currents and to withstand large voltages. Inventors of embodiments of the present disclosure have recognized that optimizing certain performance parameters of power switches may come at the expense of other factors. For example, inventors of embodiments of the present disclosure have recognized that reducing the on-state resistance (RON) of a power transistor to reduce conduction losses may come at the expense of a larger semiconductor die size and associated cost. As another example, inventors of embodiments of the present disclosure have recognized that certain techniques for reducing the on-state resistance (RON) of a power transistor may come at the further expense of reducing the breakdown voltage (BV) of the power transistor. Embodiments of the present disclosure may address one or more of these challenges.

### SUMMARY

The examples herein enable techniques for utilizing an angled trench to form a silicon carbide trench MOSFET with reduced manufacturing cost and improved on-state resistance (RON).

According to one embodiment, a trench MOSFET includes (i) a substrate formed with silicon carbide, (ii) an epitaxial layer formed with silicon carbide and disposed on the substrate, the epitaxial layer having a crystallographic structure with a growth direction that is angularly offset from a surface normal of an upper surface of the epitaxial layer, (iii) a drift region formed in a lower portion of the epitaxial layer, (iv) a base region disposed in the epitaxial layer above the drift region, (v) a source region disposed in the epitaxial layer above the base region, (vi) a trench extending through the source region and the base region, the trench having a first sidewall extending in a direction that is angularly offset from the surface normal of the upper surface of the epitaxial layer and along a first non-polar crystal plane of the crystallographic structure of the epitaxial layer, and a second sidewall extending parallel to the first sidewall in the direction that is angularly offset from the surface normal of the upper surface of the epitaxial layer and along a second non-polar crystal plane of the crystallographic structure of the epitaxial layer, and (vii) a gate formed within the trench. In some embodiments, the epitaxial layer has a 4H-SiC crystallographic structure. In the same or different embodiments, the trench has a rhomboid cross-sectional shape. In the same or different embodiments, the first non-polar crystal plane is a first a-face of the crystallographic structure, and the second non-polar crystal plane is a second a-face of the crystallographic structure. In the same or different embodiments, the first non-polar crystal plane is a first m-face of the crystallographic structure, and the second non-polar crystal plane is a second m-face of the crystallographic structure. In the same or different embodiments, the trench MOSFET further comprises a blocking region formed under the trench, the blocking region having an opposite conductivity type relative to the drift region. In the same or different embodiments, the trench MOSFET further comprises a current-spreading region disposed between the drift region and the base region, the current-spreading region having a same conductivity type at a higher doping level relative to the drift region. In the same or different embodiments, the trench MOSFET further comprises a pillar extending parallel to the trench and through the source region and the current-spreading region, the pillar having an opposite conductivity type relative to the drift region. In the same or different embodiments, the trench MOSFET is a super-junction trench MOSFET. In the same or different embodiments, the super-junction trench MOSFET comprises a pillar extending through at least a portion of the drift region in a pillar direction parallel to the trench, the pillar having an opposite conductivity type relative to the drift region. In the same or different embodiments, the pillar extends up from the drift region and through the source region.

According to another embodiment, a silicon carbide trench MOSFET includes (i) a substrate formed with silicon carbide, (ii) an epitaxial layer formed with silicon carbide and disposed on the substrate, the epitaxial layer having a 4H-SiC crystallographic structure with a growth direction that is angularly offset from a surface normal of an upper surface of the epitaxial layer, (iii) a drift region formed in a lower portion of the epitaxial layer, (iv) a base region disposed in the epitaxial layer above the drift region, (v) a source region disposed in the epitaxial layer above the base region, (vi) a trench extending through the source region and the base region, the trench having a first sidewall extending in a direction that is angularly offset from the surface normal of the upper surface of the epitaxial layer and along a first a-face of the 4H-SiC crystallographic structure of the epitaxial layer, and a second sidewall extending parallel to the first sidewall in the direction that is angularly offset from the surface normal of the upper surface of the epitaxial layer and along a second a-face of the 4H-SiC crystallographic structure of the epitaxial layer, and (vii) a gate formed within the trench. In some embodiments, the trench has a rhomboid cross-sectional shape. In the same or different embodiments, the silicon carbide trench MOSFET further comprises a blocking region formed under the trench, the blocking region having an opposite conductivity type relative to the drift region. In the same or different embodiments, the silicon carbide trench MOSFET further comprises a current-spreading region disposed between the drift region and the base region, the current-spreading region having a same conductivity type at a higher doping level relative to the drift region. In the same or different embodiments, the silicon carbide trench MOSFET further comprises a pillar extending parallel to the trench and through the source region and the current-spreading region, the pillar having an opposite conductivity type relative to the drift region. In the same or different embodiments, the silicon carbide trench MOSFET is a super-junction trench MOSFET. In the same or different embodiments, the super-junction trench MOSFET comprises a pillar extending through at least a portion of the drift region in a pillar direction parallel to the trench, the pillar having an opposite conductivity type relative to the drift region. In the same or different embodiments, the pillar extends up from the drift region and through the source region.

Anther embodiments includes a method for forming a trench MOSFET, wherein the method includes (i) providing a substrate formed with silicon carbide, (ii) growing an epitaxial layer with a crystallographic structure that has a growth direction that is angularly offset from a surface normal of an upper surface of the epitaxial layer, (iii) forming a drift region in a lower portion of the epitaxial layer, (iv) forming a base region in the epitaxial layer above the drift region, (v) forming a source region in the epitaxial layer above the base region, (vi) etching a trench through the source region and the base region, the trench including a first sidewall extending in a direction that is angularly offset from the surface normal of the upper surface of the epitaxial layer and along a first non-polar crystal plane of the crystallographic structure of the epitaxial layer, and a second sidewall extending parallel to the first sidewall in the direction that is angularly offset from the surface normal of the upper surface of the epitaxial layer and along a second non-polar crystal plane of the crystallographic structure of the epitaxial layer, and (vii) forming a gate within the trench. In some embodiments, the epitaxial layer has a 4H-SiC crystallographic structure. In the same or different embodiments, the trench has a rhomboid cross-sectional shape. In the same or different embodiments, the first non-polar crystal plane is a first a-face of the crystallographic structure, and the second non-polar crystal plane is a second a-face of the crystallographic structure. In the same or different embodiments, the first non-polar crystal plane is a first m-face of the crystallographic structure, and the second non-polar crystal plane is a second m-face of the crystallographic structure. In the same or different embodiments, the method further comprises forming a blocking region under the trench, the blocking region having an opposite conductivity type relative to the drift region. In the same or different embodiments, the method further comprises forming a current-spreading region between the drift region and the base region, the current-spreading region having a same conductivity type at a higher doping level relative to the drift region. In the same or different embodiments, the method further comprises forming a pillar through the source region and the current-spreading region and parallel to the trench, the pillar having an opposite conductivity type relative to the drift region. In the same or different embodiments, the method further comprises forming a pillar extending through at least a portion of the drift region in a pillar direction parallel to the trench, the pillar having an opposite conductivity type relative to the drift region to form an angled super-junction structure. In the same or different embodiments, the pillar extends up from the drift region and through the source region.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a crystal plane diagram of silicon carbide (SiC) in accordance with embodiments of the present disclosure.

FIG. 2 illustrates a plot diagram illustrating electric properties of various crystal planes of the 4H-SiC polytype of silicon carbide in accordance with embodiments of the present disclosure.

FIG. 3 illustrates a cross-sectional view of a silicon carbide semiconductor die during manufacturing of a trench MOSFET.

FIG. 4 illustrates stacking layers of silicon carbide (SiC) in accordance with embodiments of the present disclosure.

FIG. 5 illustrates a cross-sectional view of a silicon carbide semiconductor die during manufacturing of a trench MOSFET.

FIG. 6 illustrates a cross-sectional view of a silicon carbide semiconductor die during manufacturing of a trench MOSFET in accordance with embodiments of the present disclosure.

FIG. 7 illustrates a cross-sectional view of a trench MOSFET in accordance with embodiments of the present disclosure.

FIG. 8 illustrates a cross-sectional view of a trench MOSFET in accordance with embodiments of the present disclosure.

FIG. 9 illustrates a cross-sectional view of a trench MOSFET in accordance with embodiments of the present disclosure.

FIG. 10 illustrates a cross-sectional view of a trench MOSFET in accordance with embodiments of the present disclosure.

FIG. 11 illustrates method 1100 for manufacturing a trench MOSFET in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other elements and connections.

Further, although the terms “first,” “second,” and so forth may be used herein to describe various elements, these elements should not be limited by these terms. Terms such as “first” and “second” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element. As used herein, the term “and/or” includes any and all combinations of one or more of the associated listed items.

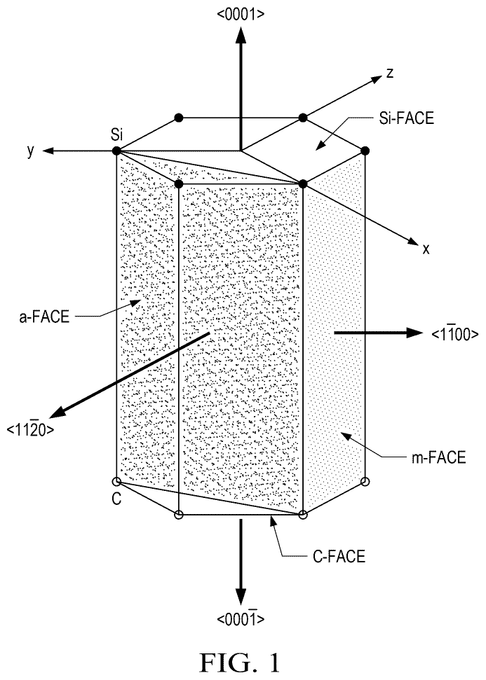

FIG. 1 illustrates a crystal plane diagram of silicon carbide (SiC) in accordance with embodiments of the present disclosure. Specifically, FIG. 1 illustrates a crystal plane diagram of the 4H-SiC polytype of silicon carbide, which has a hexagonal crystal structure with a four-layer stacking sequence of silicon and carbon atoms. As shown in FIG. 1, the Miller index may be utilized to label specific atomic planes in the silicon carbide structure.

The silicon face (Si-face) is the surface terminated by silicon (Si) atoms and may be labeled as the <0001> plane. The carbon face (C-face) is the surface terminated by carbon (C) atoms and may be labeled as the <0001̅> plane. Various other surfaces may also be labeled using the Miller index. For example, the m-face may be labeled as the <11̅00> plane, and may have a non-polar surface containing an equal number of silicon and carbon atoms. As another example, the a-face may be labeled as the <112̅0> plane, which may be another non-polar surface containing an equal number of silicon and carbon atoms. Due to the non-polar nature of the m-face and the a-face, these planes may have lower interface trap densities and higher electron mobility than, for example, the Si-face.

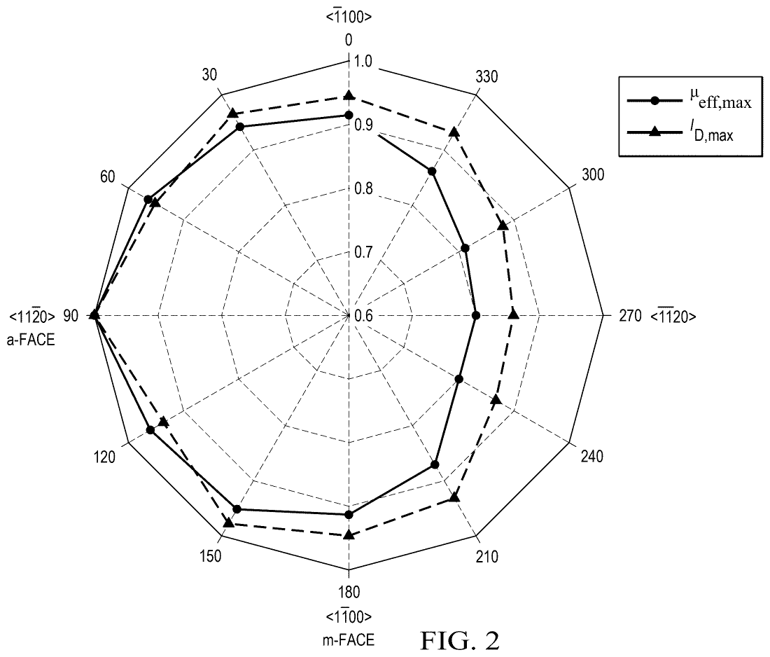

FIG. 2 illustrates a plot diagram illustrating electric properties of various crystal planes of the 4H-SiC polytype of silicon carbide in accordance with embodiments of the present disclosure. As shown in FIG. 2, the a-face <112̅0> and the m-face <11̅00> may have higher maximum electron mobilities (μ_{eff,max}) and maximum current densities (I_{D,max}) relative to other planes in the crystallographic structure of 4H-SiC. As described in further detail below, the high electron mobility of the a-face <112̅0>, for example, may be utilized to improve the on-state resistance of trench MOSFETs formed in silicon carbide.

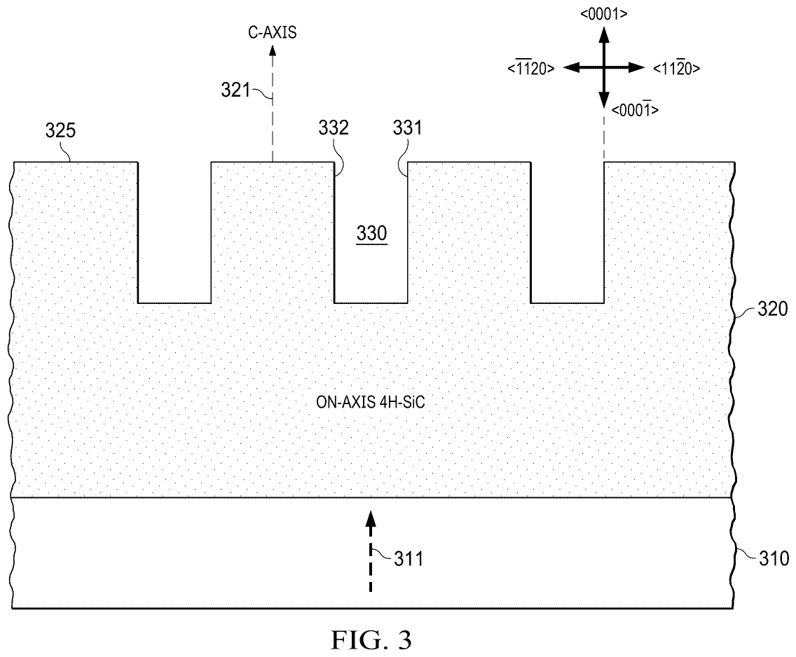

FIG. 3 illustrates a cross-sectional view of a silicon carbide semiconductor die during manufacturing of a trench MOSFET. Substrate 310 may first be provided. Substrate 310 may be formed with silicon carbide. In some embodiments, substrate 310 may include an SiC single crystal wafer, which may form the seed for the epitaxial growth. Substrate 310 may be disposed about a center axis 311, which may be the center axis of the physical dimensions of substrate 310.

During manufacturing, epitaxial layer 320 may be grown on substrate 310 by a 4H-SiC epitaxial growth process for example. Epitaxial layer 320 may be grown in an on-axis manner, where the growth direction represented by c-axis 321 is perpendicular to the surface of the seed wafer formed by substrate 310. For such on-axis growth, the c-axis 321 may be perpendicular to the upper surface 325 of epitaxial layer 320, or in other words, parallel to the surface normal at the upper surface 325 of epitaxial layer 320. In addition, the a-face <112̅0> and the m-face <11̅00> may likewise be perpendicular to the upper surface 325 of epitaxial layer 320.

During manufacturing of a trench MOSFET, trenches 330 may be etched in the upper surface 325 of epitaxial layer 320. Each trench 330 may include a first sidewall 331 and a second sidewall 332. Although not shown in FIG. 3, a MOSFET gate structure may be formed within trench 330. Further, a source region, a channel region, and a current-spreading region may be respectively disposed in the mesas to form a vertical-channel MOSFET. In some embodiments, each trench 330 may be aligned such that first sidewall 331 and second sidewall 332 are each disposed along an a-face <112̅0> of the crystallographic structure of epitaxial layer 320. Accordingly, the MOSFET channels formed along first sidewall 331 and second sidewall 332 may benefit from the high electron mobility of the a-faces <112̅0> of the on-axis 4H-SiC structure.

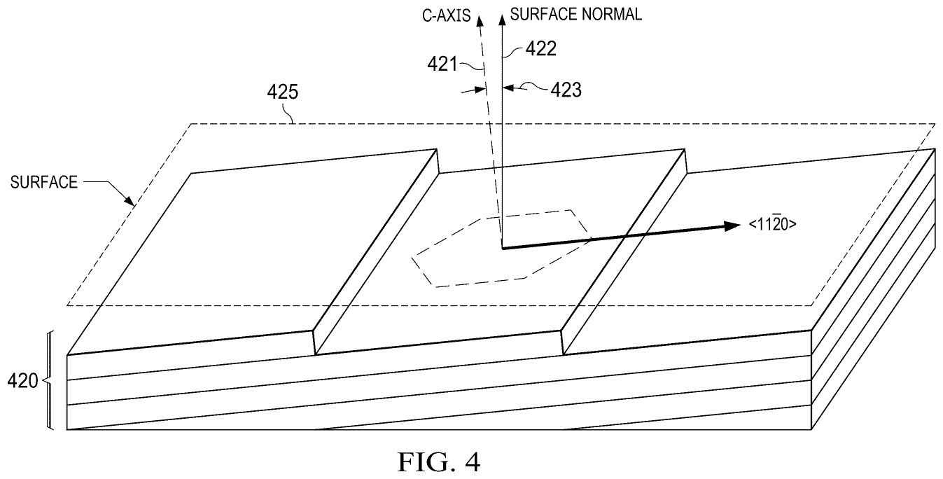

FIG. 4 illustrates stacking layers of silicon carbide (SiC) in accordance with embodiments of the present disclosure. Specifically, FIG. 4 illustrates stacking layers of the 4H-SiC polytype of silicon carbide grown with an off-axis epitaxial growth process.

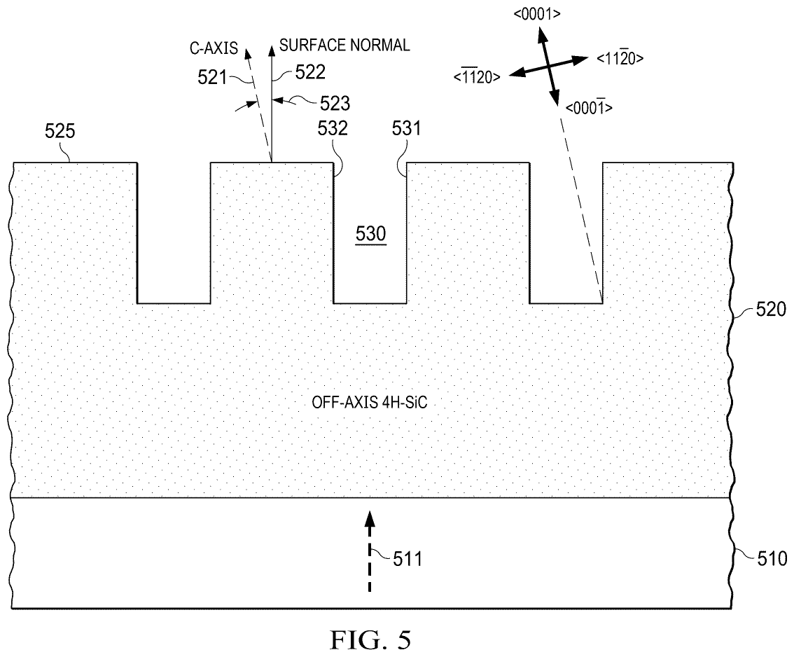

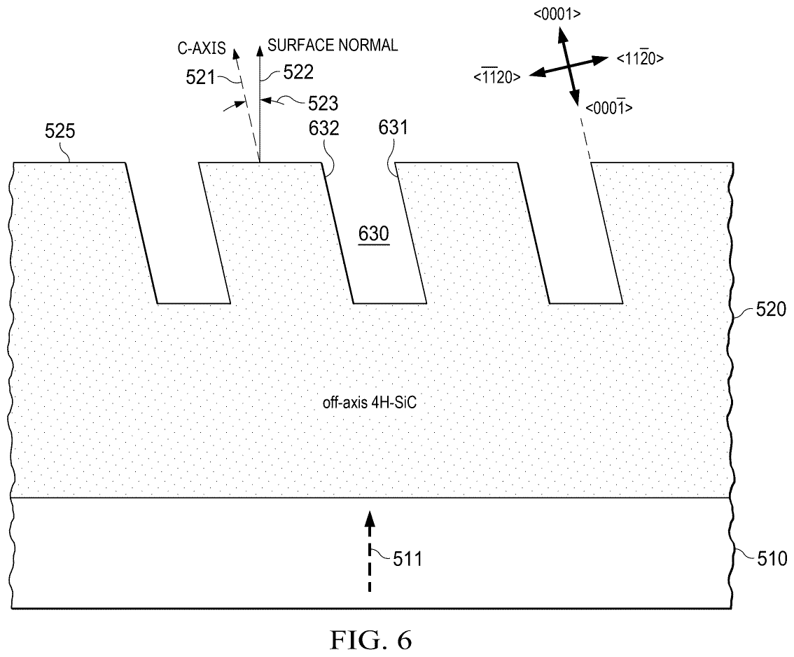

In some embodiments, an off-axis epitaxial growth process may be used to form the epitaxial layer (such as epitaxial layer 420 described below with reference to FIG. 4 and epitaxial layer 520 described below with reference to FIGS. 5 and 6). Such an off-axis epitaxial growth may allow the crystal growth to maintain the polytype of the seed at a higher growth rate than for on-axis epitaxial growth. The use of off-axis epitaxial growth may thus reduce the cost of the epitaxial growth step when manufacturing devices in silicon carbide, such as the trench MOSFETs disclosed herein.

The off-axis epitaxial growth may produce an angular offset 423 between the growth direction represented by c-axis 421 and the surface normal 422 at the upper surface 425 of epitaxial layer 420. In some embodiments, the angular offset 423 may be for example, 2, 4, 5, 10, 15, 20 degrees or more. The off-axis epitaxial growth may accordingly also result in an a-face <112̅0> that is angularly offset at an oblique angle from the upper surface 425 of epitaxial layer 420. As described in further detail below, inventors of embodiments of the present disclosure have recognized that such off-axis growth may impact the alignment of trench sidewalls with a higher-electron-mobility crystallographic plane, such as the a-face <112̅0>.

FIG. 5 illustrates a cross-sectional view of a silicon carbide semiconductor die during manufacturing of a trench MOSFET. Substrate 510 may first be provided. Substrate 510 may be formed with silicon carbide. In some embodiments, substrate 510 may include an SiC single crystal wafer, which may form the seed for the epitaxial growth. Substrate 510 may be disposed about a center axis 511, which may be the center axis of the physical dimensions of substrate 510, distinct from the stacking direction of the SiC crystal forming the seed for epitaxial growth of epitaxial layer 520.

During manufacturing, epitaxial layer 520 may be grown on substrate 510 by a 4H-SiC epitaxial growth process for example. Epitaxial layer 320 may be grown in an off-axis manner, with a growth direction represented by c-axis 521. As shown the FIG. 5, c-axis 521 may have an angular offset 523 from the surface normal 522 at the upper surface 525 of epitaxial layer 520. Accordingly, the a-face <112̅0> may have a similar angular offset from the surface normal 522 of the upper surface 525 of epitaxial layer 520.

During manufacturing of a trench MOSFET, trenches 530 may be etched in the upper surface 525 of epitaxial layer 520. Each trench 530 may include a first sidewall 531 and a second sidewall 532. Although not shown in FIG. 5, a MOSFET gate structure may be formed within trench 530. Further, a source region, a channel region, and a current-spreading region may be respectively disposed in the mesas to form a vertical-channel MOSFET. As shown in FIG. 5, trenches 530 may be etched at an angle perpendicular to the upper surface 525 of epitaxial layer 520. Accordingly, the first sidewall 531 and second sidewall 532 may be angularly offset from the a-face <112̅0> of the crystallographic structure of epitaxial layer 520. As described in further detail below with reference to FIGS. 6-10, however, such trenches may in some embodiments be formed at an angular offset to align the first and second sidewalls of the trench with the a-face <112̅0> of the crystallographic structure of the off-axis growth direction of epitaxial layer 520.

FIG. 6 illustrates a cross-sectional view of a silicon carbide semiconductor die during manufacturing of a trench MOSFET in accordance with embodiments of the present disclosure. As shown in FIG. 6, trenches 630 may be etched in the upper surface 525 of epitaxial layer 520. Each trench 630 may include a first sidewall 631, as well as a second sidewall 632 opposing the first sidewall 631. Although not shown in FIG. 6, a MOSFET gate structure may be formed within trench 630. Further, a source region, a channel region, and a current-spreading region may be respectively disposed in the mesas to form the MOSFET.

As shown in FIG. 6, trenches 630 may be etched at the same angular offset 523 as the c-axis 521 relative to the surface normal 522 of the of the upper surface 525 of epitaxial layer 520. Trench 630 may thus have a rhomboid cross-sectional shape. During manufacturing, the angled etch may be performed with, for example, a dry etching process. In some embodiments, the ions used to perform the dry etch may be projected toward the surface of epitaxial layer 520 at an angular offset. In other embodiments, the ions used to perform the dry etch may be projected straight downward while a substrate 510 and epitaxial layer 520 are tilted at an oblique angle relative to the direction of ion projection.

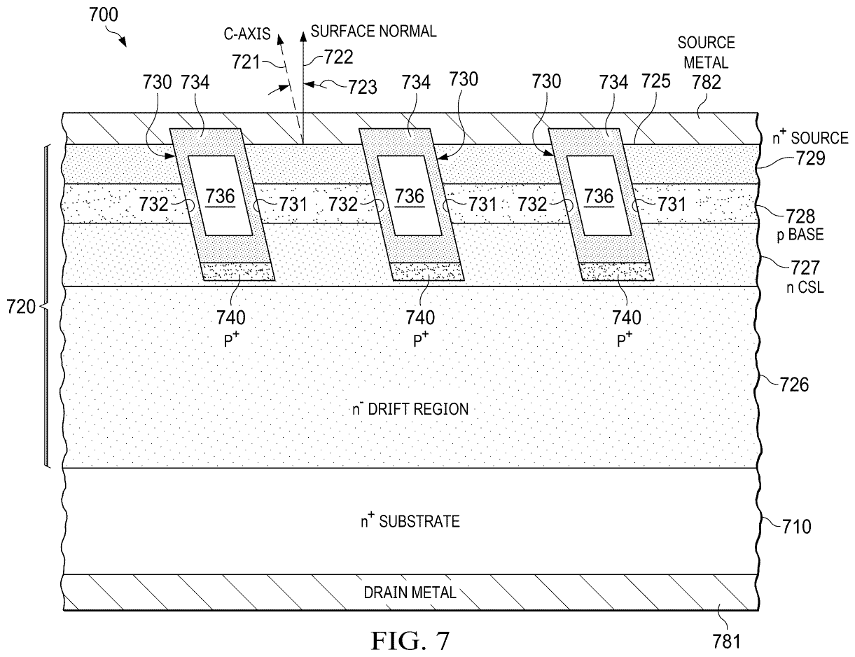

In some embodiments, each trench 630 may be arranged such that first sidewall 631 and second sidewall 632 are each disposed along an a-face <112̅0> of the crystallographic structure of epitaxial layer 520. Accordingly, the MOSFET channels formed along first sidewall 631 and second sidewall 632 may benefit from the high electron mobility of the a-faces <112̅0> of the off-axis 4H-SiC structure. Further, such advantages may be realized in combination with the improved manufacturing cost of forming epitaxial layer 520 with an off-axis growth process. Further embodiments of trench MOSFETs utilizing such off-axis epitaxial growth and angled trenches are described in detail below with reference to FIGS. 7-10.

FIG. 7 illustrates a cross-sectional view of trench MOSFET 700 in accordance with embodiments of the present disclosure. As shown in FIG. 7, trench MOSFET 700 may include substrate 710, epitaxial layer 720, drift region 726, current-spreading region 727, base region 728, source region 729, and trenches 730 filled with dielectric material 734 and gate 736. Further metal layers may also be added to trench MOSFET 700, including source metal 782 electrically coupled to source region 729, and drain metal 781 electrically coupled to substrate 710. As described below, substrate 710 and epitaxial layer 720 may be formed with silicon carbide. Accordingly, trench MOSFET 700 may also be referred to as a silicon carbide trench MOSFET.

Substrate 710 may be formed with silicon carbide. Substrate 710 may have, for example, a 4H-SiC crystallographic structure. In some embodiments, substrate 710 may include an SiC single crystal wafer, which may form the seed for the epitaxial growth of epitaxial layer 720. Further, substrate 710 may have a heavy doping of a first conductivity type. For example, in embodiments where trench MOSFET 700 is an n-channel MOSFET (also referred to as an NMOS), substrate may have a heavy n+ doping.

Epitaxial layer 720 may be formed with silicon carbide and disposed on substrate 710. For example, as described above, substrate 710 may form the seed for growing epitaxial layer 720. In some embodiments, epitaxial layer 720 may have a 4H-SiC crystallographic structure. Further, epitaxial layer 720 may have a crystallographic structure with a growth direction that is angularly offset from a surface normal 722 of an upper surface 725 of epitaxial layer 720. For example, epitaxial layer 720 may be formed by an off-axis epitaxial growth that produces an angular offset 723 between the growth direction (represented by c-axis 721 in FIG. 7) and the surface normal 722 of the upper surface 725 of epitaxial layer 720. In some embodiments, the angular offset 723 may be for example, 2, 4, 5, 10, 15, 20 degrees or more. For example, in some embodiments, the angular offset 723 may be set to a value of, for example 15 degrees, that optimally limits crystallographic defects during the epitaxial growth and achieves desirable interface properties.

Drift region 726 may be formed in a lower portion of epitaxial layer 720 that is adjacent to substrate 710. Drift region 726 may have a lower doping concentration of the same conductivity type as substrate 710. For example, in embodiments where trench MOSFET 700 is an n-channel MOSFET, drift region 726 may have a light n− doping. In some embodiments, the light n− doping may be added by ion implantation or other means after epitaxial layer 720 is grown. In other embodiments, the light n− doping may be included as part of the epitaxial growth, and thus drift region 726 may also be referred to as being formed by the lower portion of epitaxial layer 720.

As shown in FIG. 7, trench MOSFET 700 may optionally include current-spreading region 727 (also referred to as a current-spreading layer or CSL) disposed in epitaxial layer 720 between drift region 726 and base region 728. Current-spreading region 727 may have the same conductivity type at a higher doping level relative to drift region 726. For example, in embodiments where trench MOSFET 700 is an n-channel MOSFET, current-spreading region 727 may have an n-type doping at a higher doping concentration level than drift region 726. The n-type doping for current-spreading region 727 may be added during the epitaxial growth process or by additional ion implantation after the epitaxial growth process. During operation of trench MOSFET 700, the higher doping concentration of current-spreading region 727 may help spread the flow of current more evenly across drift region 726, thereby reducing the on-state resistance RON of trench MOSFET 700.

Base region 728 may be disposed in epitaxial layer 720 above drift region 726. As shown in FIG. 7 for embodiments that include current-spreading region 727, base region 728 may disposed above both drift region 726 and current-spreading region 727. Base region 728 may have an opposite conductivity type relative to drift region 726, current-spreading region 727, and source region 729. For example, in embodiments where trench MOSFET 700 is an n-channel MOSFET, base region 728 may have a p-type doping, which may be referred to as the opposite conductivity type of the n-type doping of drift region 726, current-spreading region 727, and source region 729. In some embodiments, the p-type doping used to form base region 728 may be added, by ion implantation for example, after the growth of epitaxial layer 720.

Source region 729 may be disposed in epitaxial layer 720 above base region 728. Source region 729 may have the same conductivity type at a higher doping level relative to drift region 726. For example, in embodiments where trench MOSFET 700 is an n-channel MOSFET, source region 729 may have an n-type doping at a higher doping concentration level than drift region 726. The n-type doping for source region 729 may be added during the epitaxial growth process or by additional ion implantation after the epitaxial growth process.

After formation of the gate structures, which are described in further detail below, source metal 782 may be electrically coupled to source region 729. For simplicity, source metal 782 is illustrated in FIG. 7 as being disposed on top of epitaxial layer 720, and specifically on top of source region 729 disposed along the upper surface 725 of epitaxial layer 720. Some embodiments, however, may include further silicide and/or source-contact layers between source region 729 and source metal 782 to facilitate a low-resistance ohmic contact that electrically couples source region 729 to source metal 782.

Further, backside metal processing may be performed to add drain metal 781 to the bottom side of substrate 710, opposite of epitaxial layer 720. For simplicity, drain metal 781 is illustrated in FIG. 7 as being disposed in direct contact with the backside of substrate 710. Some embodiments, however, may include further silicide and/or contact layers between substrate 710 and drain metal 781 to facilitate a low-resistance ohmic contact that electrically couples substrate 710 to drain metal 781.

Trench MOSFET 700 may include trenches 730 extending from the upper surface of epitaxial layer 720 and through source region 729 and base region 728. As shown in FIG. 7 (and similar to trenches 630 shown in FIG. 6), trenches 730 may be etched in the direction of c-axis 721. In other words, trenches 730 may be formed with the same angular offset 723 as the c-axis 721 relative to the surface normal 722 of the upper surface 725 of epitaxial layer 720. Due to this angular offset, each instance of trench 730 may have a rhomboid cross-sectional shape.

The first sidewall 731 of each instance of trench 730 may extend in a direction that is angularly offset from the surface normal 722 of the upper surface 725 of the epitaxial layer 720. Specifically, the first sidewall 731 may extend in the same direction of the c-axis 721 that is angularly offset from the surface normal 722 of the upper surface 725 of the epitaxial layer 720. Further, the second sidewall 732 of each instance of trench 730 may extend parallel to the first sidewall 731 in the direction that is angularly offset from the surface normal 722 of the upper surface 725 of the epitaxial layer 720. Specifically, the second sidewall 732 may extend parallel to the first sidewall 731 in the same direction of the c-axis 721 that is angularly offset from the surface normal 722 of the upper surface 725 of the epitaxial layer 720. In some embodiments, the angular offset 723 may be for example, 2, 4, 5, 10, 15, 20 degrees or more. Given the non-perpendicular relationship between the first and second sidewalls 731 and 732 of trench 730 relative to the upper surface 725 of epitaxial layer 720, trench 730 (as well as first sidewall 731 and second sidewall 732) may also be referred to as being disposed at an oblique angle relative to the upper surface 725 of epitaxial layer 720.

During manufacturing, the angled etch may be performed with, for example, a dry etching process. In some embodiments, the ions used to perform the dry etch may be projected toward the surface of epitaxial layer 720 at an angular offset. In other embodiments, the ions used to perform the dry etch may be projected straight downward while a substrate 710 and epitaxial layer 720 are tilted at an oblique angle relative to the direction of ion projection.

In some embodiments, each instance of trench 730 may be arranged such that first sidewall 731 extends along a first non-polar crystal plane of the crystallographic structure of epitaxial layer 720, and that second sidewall extends along a second non-polar crystal plane of the crystallographic structure of epitaxial layer 720. In some embodiments, the first non-polar crystal plane may be a first a-face <112̅0> of the crystallographic structure of epitaxial layer 720, while the second non-polar crystal plane may be a second a-face <112̅0> of the crystallographic structure of epitaxial layer 720. In other embodiments, the first non-polar crystal plane may be a first m-face <11̅00> of the crystallographic structure of epitaxial layer 720, while the second non-polar crystal plane may be a second m-face <11̅00> of the crystallographic structure of epitaxial layer 720. Accordingly, the MOSFET channels formed along first sidewall 731 and second sidewall 732 may benefit from the high electron mobility of the a-faces <112̅0> or the m-faces <11̅00> of epitaxial layer 720. Further, such advantages may be realized in combination with the improved manufacturing cost of forming epitaxial layer 720 with an off-axis growth process.

The gate structures for trench MOSFET 700 may be disposed in trenches 730. For example, as shown in FIG. 7, an instance of gate 736 may be formed within each instance of trench 730. In some embodiments, a thin layer of dielectric material 734 may be deposited or grown to line the bottom of trench 730 as well as the first sidewall 731 and second sidewall 732 after trench 730 is etched. The dielectric material 734 may include, for example, silicon dioxide, silicon nitride, or any other material suitable to form a gate dielectric. Gate 736 may then be deposited to fill remaining area within trench 730. Gate 736 may be formed, for example, with polysilicon. Gate 736 may be disposed in a striped pattern extending into the page shown in FIG. 7, and may be coupled via one or more gate contacts and/or gate runners to a gate-pad metal at another location on the semiconductor die on which trench MOSFET 700 is formed. The portions of dielectric material 734 disposed between gate 736 and first sidewall 731, and between gate 736 and second sidewall 732, may serve as a gate dielectric. Channels from source region 729, through base region 728, and to current-spreading region 727 and/or drift region 726, may thus be formed in base region 728 adjacent to first sidewall 731 and adjacent to second sidewall 732. After the polysilicon or other material forming gate 736 is deposited within trench 730, further portions of dielectric material 734 may be deposited above gate 736 to electrically insulate gate 736 from the above source metal 782.

During operation of trench MOSFET 700, current may flow from drain metal 781, through substrate 710, through drift region 726, through current-spreading region 727, where current may then flow to source region 729 through the channels opened in base region 728 by the application of a sufficient gate voltage to various instances of gate 736. As described above, the MOSFET channels formed along first sidewall 731 and second sidewall 732 may benefit from the high electron mobility of the a-faces <112̅0> or the m-faces <11̅00> of the crystallographic structure of epitaxial layer 720 along which those sidewalls are formed. The alignment of first sidewall 731 and second sidewall 732 along respective a-faces or respective m-faces of the crystallographic structure of epitaxial layer 720 may thus reduce the on-state resistance (RON) of trench MOSFET 700.

As shown in FIG. 7, trench MOSFET 700 may further include blocking region 740. Blocking region 740 may be formed under gate 736, and specifically under the trench 730 within which gate 736 is disposed. In some embodiments, blocking region 740 may have an opposite conductivity type relative to drift region 726. For example, in embodiments where trench MOSFET 700 is an n-channel MOSFET, blocking region 740 may have a heavy p-type doping, which may be referred to as the opposite conductivity type of the n-type doping of drift region 726, current-spreading region 727, and source region 729. In some embodiments, the p-type doping used to form blocking region 740 may be added, by ion implantation for example, after the growth of epitaxial layer 720. For example, blocking region 740 may be formed after the etching of trench 730, and may utilize the same masking as the dry etch to self-align blocking region 740 under trench 730. Blocking region 740 may provide a shield protecting the above gate structures (including the portions of dielectric material 734 disposed along first sidewall 731 and second sidewall 732) from electric fields in drift region 726 when a high voltage is applied across the drain and the source of trench MOSFET 700, thereby improving the breakdown voltage (BV) of trench MOSFET 700.

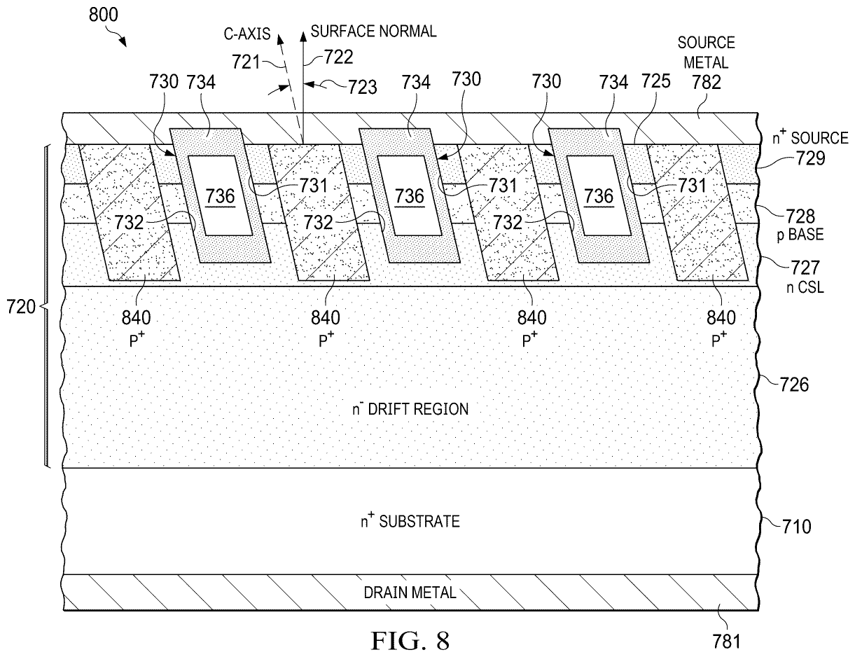

FIG. 8 illustrates a cross-sectional view of trench MOSFET 800 in accordance with embodiments of the present disclosure. As shown in FIG. 8, trench MOSFET 800 may include substrate 710, epitaxial layer 720, drift region 726, current-spreading region 727, base region 728, source region 729, source metal 782, drain metal 781, and trenches 730 (filled with dielectric material 734 and gate 736), each of which may be configured and disposed in a similar manner as described above with reference to trench MOSFET 700 in FIG. 7.

In addition, trench MOSFET 800 may include a pillar 840 extending parallel to trench 730 and through source region 729, base region 728, and current-spreading region 727. As shown in FIG. 8, an instance of pillar 840 may be located between each consecutive two instances of trench 730. In some embodiments, pillar 840 may extend through current-spreading region 727 to depth less than the maximum depth of current-spreading region 727 as shown in FIG. 8. In other embodiments, pillar 840 may extend through current-spreading region 727 to a depth equal to or greater than the maximum depth of current-spreading region 727.

Pillar 840 may have an opposite conductivity type relative to drift region 726. For example, in embodiments where trench MOSFET 800 is an n-channel MOSFET, pillar 840 may have a heavy p-type doping, which may be referred to as the opposite conductivity type of the n-type doping of drift region 726, current-spreading region 727, and source region 729. In some embodiments, pillar 840 may have a heavier p-type doping concentration than base region 728. In some embodiments, the p-type doping used to form pillar 840 may be added, by ion implantation for example, after the growth of epitaxial layer 720. Pillar 840 may provide shielding for the gate structures (including the portions of dielectric material 734 disposed along first sidewall 731 and second sidewall 732) from electric fields in drift region 726 when a high voltage is applied across the drain and the source of trench MOSFET 800, thereby improving the breakdown voltage (BV) of trench MOSFET 800.

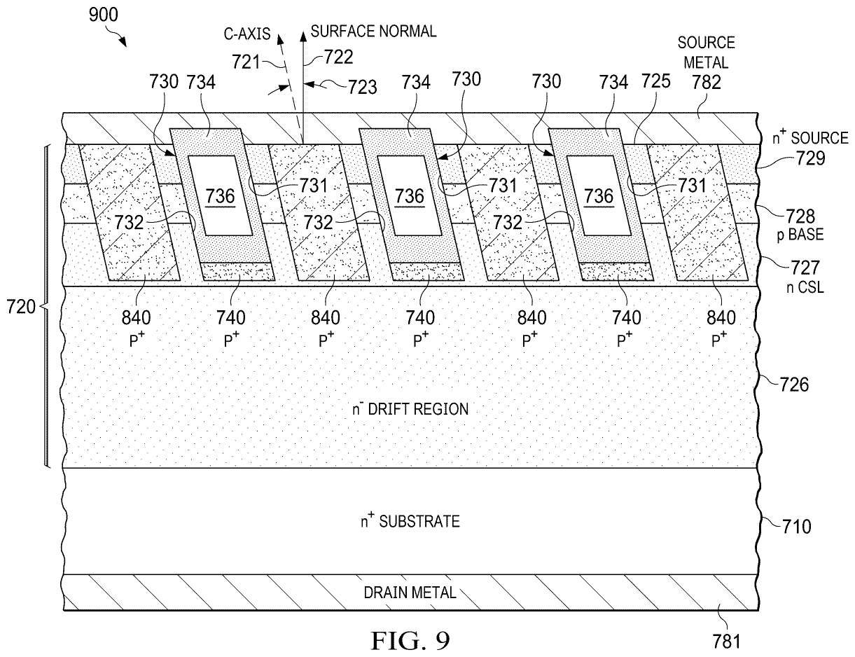

FIG. 9 illustrates a cross-sectional view of trench MOSFET 900 in accordance with embodiments of the present disclosure. As shown in FIG. 9, trench MOSFET 900 may include substrate 710, epitaxial layer 720, drift region 726, current-spreading region 727, base region 728, source region 729, source metal 782, drain metal 781, and trenches 730 (filled with dielectric material 734 and gate 736), each of which may be configured and disposed in a similar manner as described above with reference to trench MOSFET 700 in FIG. 7.

In addition, trench MOSFET 900 may include both blocking region 740 (described above with reference to FIG. 7) and pillar 840 (described above with reference to FIG. 8). The inclusion of both pillar 840 and blocking region 740 may provide additional protection for the gate structure of trench MOSFET 900 from electric fields in drift region 726 when a high voltage is applied across the drain and the source of trench MOSFET 800, thereby improving the breakdown voltage (BV) of trench MOSFET 900.

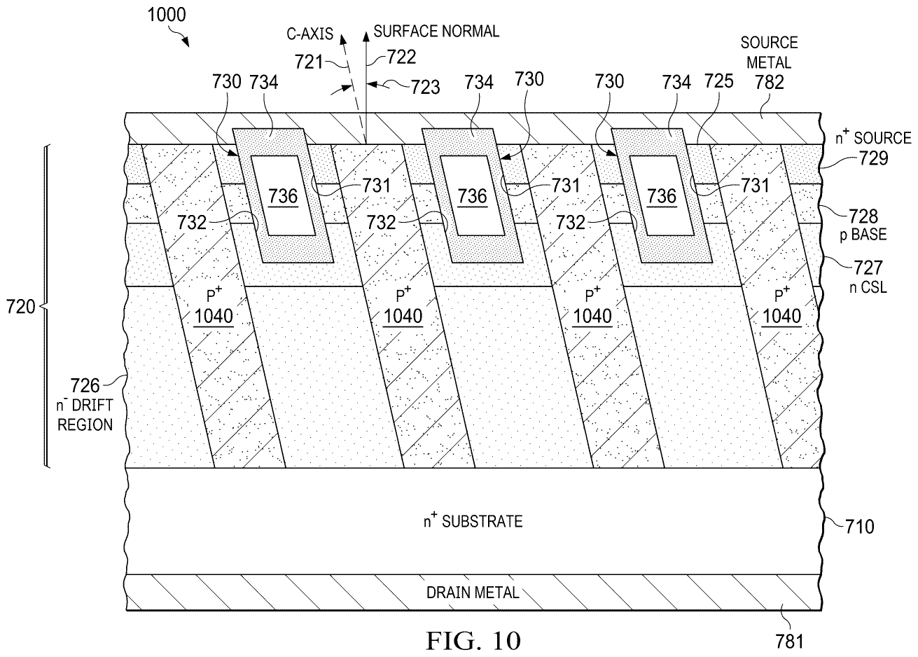

FIG. 10 illustrates a cross-sectional view of trench MOSFET 1000 in accordance with embodiments of the present disclosure. As shown in FIG. 10, trench MOSFET 1000 may include substrate 710, epitaxial layer 720, drift region 726, current-spreading region 727, base region 728, source region 729, source metal 782, drain metal 781, and trenches 730 (filled with dielectric material 734 and gate 736), each of which may be configured and disposed in a similar manner as described above with reference to trench MOSFET 700 in FIG. 7. Although not shown in FIG. 10, trench MOSFET 1000 may in some embodiments also include blocking regions 740 formed under instances of trench 730 and gate 736 as described above with reference to FIG. 7.

In addition, trench MOSFET 1000 may include a pillar 1040 extending through at least a portion of drift region 726 in a pillar direction parallel to trench 730. For example, similar to first sidewall 731 and second sidewall 732 of trench 730, pillar 1040 may extend through at least a portion of drift region 726 in the direction of c-axis 721 with an angular offset 723 to the surface normal 722 of the upper surface 725 of epitaxial layer 720. As shown in FIG. 10, an instance of pillar 1040 may be disposed between each consecutive two instances of trench 730. In some embodiments, such as shown in FIG. 10, pillar 1040 may extend through drift region 726, and further extend up from drift region 726 and through current-spreading region 727, base region 728, and through source region 729 to the upper surface 725 of epitaxial layer 720. In other embodiments, pillar 1040 may extend through drift region 726, from the bottom of drift region 726 adjacent to substrate 710 to the top of drift region 726 adjacent to current-spreading region 727.

Pillar 1040 may have an opposite conductivity type relative to drift region 726. For example, in embodiments where trench MOSFET 1000 is an n-channel MOSFET, pillar 1040 may have a heavy p-type doping, which may be referred to as the opposite conductivity type of the n-type doping of drift region 726, current-spreading region 727, and source region 729. In some embodiments, pillar 1040 may have a heavier p-type doping concentration than base region 728. In some embodiments, the p-type doping used to form pillar 1040 may be added, by ion implantation for example, after the growth of epitaxial layer 720.

The extension of pillar 1040 through drift region 726 may form a super-junction to improve the breakdown voltage (BV) of trench MOSFET 1000. Trench MOSFET 1000 may thus also be referred to as a super-junction trench MOSFET. In embodiments where trench MOSFET 1000 is an n-channel MOSFET, the various instances of pillar 1040 may include a p-type doping while drift region 726 includes n-type doping. The respective p-type and n-type doping concentrations of pillar 1040 and drift region 726 may be designed such that the instances of pillar 1040 are charged balanced with the remaining n-type portions of drift region 726. The charge balance of pillars 1040 with the remaining portions of drift region 726 may provide a higher blocking voltage, and thus a higher breakdown voltage (BV), as compared to a fully n-type drift region. In some embodiments, presence of pillars 1040 may allow for a higher n-type doping concentration of drift region 726 for a given breakdown voltage (BV) requirement. During operation of trench MOSFET 1000, current may flow from drain metal 781, through substrate 710, through the n-type portions of drift region 726, through current-spreading region 727, where current may then flow to source region 729 through the various channels opened in base region 728 by the application of a sufficient gate voltage to various instances of gate 736. The higher doping concentration of the n-type portions of drift region 726 (remaining after pillars 1040 are implanted) may provide for a lower-resistance current path through drift region 726, and thus a lower on-state resistance (RON) for a given die area of trench MOSFET 1000 as a whole.

As shown in FIG. 10, and as described above, pillars 1040 may in some embodiments extend further from drift region 726, and up through current-spreading region 727, base region 728, and through source region 729 to the upper surface 725 of epitaxial layer 720. Similar to pillars 840 described above with reference to FIG. 8, the upper portion of pillars 1040 extending through current-spreading region 727, base region 728, and source region 729 may provide additional shielding for the gate structures (including the portions of dielectric material 734 disposed along first sidewall 731 and second sidewall 732) from electric fields in drift region 726 when a high voltage is applied across the drain and the source of trench MOSFET 1000, thereby improving the breakdown voltage (BV) of trench MOSFET 1000.

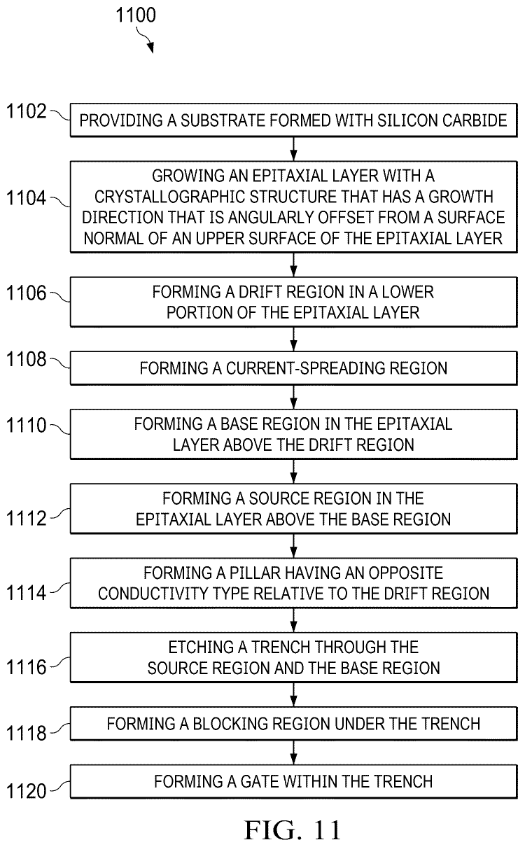

FIG. 11 illustrates method 1100 for manufacturing a trench MOSFET in accordance with embodiments of the present disclosure. Method 1100 may be performed with fewer or more steps than shown in FIG. 11. Moreover, steps of method 1100 may be omitted, repeated, performed in parallel, performed in a different order than shown in FIG. 11, or performed recursively. One or more steps of method 1100, although shown in an order, may be performed at the same time or in a re-ordered manner. For example, although the steps illustrated in FIG. 11 generally address the formation of layers in a direction from the bottom of the semiconductor substrate toward the upper surface of the semiconductor substrate, different doping implants at different depths may be utilized in any suitable order to form the regions described herein.

Step 1102 may include providing a substrate formed with silicon carbide. For example, as described above with reference to FIG. 7, substrate 710 may be provided. In some embodiments, substrate 710 may have a 4H-SiC crystallographic structure. Substrate 710 may include an SiC single crystal wafer, which may form the seed for the epitaxial growth of epitaxial layer 720.

Step 1104 may include growing an epitaxial layer with a crystallographic structure that has a growth direction that is angularly offset from a surface normal of an upper surface of the epitaxial layer. For example, as described above with reference to FIG. 7, epitaxial layer 720 may be grown with a 4H-SiC crystallographic structure using substrate 710 as the seed for the epitaxial growth. Further, epitaxial layer 720 may have a crystallographic structure with a growth direction that is angularly offset from a surface normal 722 of an upper surface 725 of epitaxial layer 720. For example, epitaxial layer 720 may be formed by an off-axis epitaxial growth that produces an angular offset 723 between the growth direction (represented by c-axis 721 in FIG. 7) and the surface normal 722 of the upper surface 725 of epitaxial layer 720.

Step 1106 may include forming a drift region in a lower portion of the epitaxial layer. For example, as described above with reference to FIG. 7, drift region 726 may be formed in a lower portion of epitaxial layer 720 that is adjacent to substrate 710. In embodiments where trench MOSFET 700 is an n-channel MOSFET, drift region 726 may have a light n− doping. In some embodiments, the light n− doping may be added by ion implantation or other means after epitaxial layer 720 is grown. In other embodiments, the light n− doping may be included as part of the epitaxial growth in step 1104.

Step 1108 may include forming a current-spreading region. For example, as described above with reference to FIG. 7, trench MOSFET 700 may optionally include current-spreading region 727 (also referred to as a current-spreading layer or CSL) disposed in epitaxial layer 720 between drift region 726 and base region 728. Current-spreading region 727 may have the same conductivity type at a higher doping level relative to drift region 726. For example, in embodiments where trench MOSFET 700 is an n-channel MOSFET, current-spreading region 727 may have an n-type doping at a higher doping concentration level than drift region 726. The n-type doping for current-spreading region 727 may be added during the epitaxial growth process of step 1104, or by additional ion implantation after the epitaxial growth process of step 1104. During operation of trench MOSFET 700, the higher doping concentration of current-spreading region 727 may help spread the flow of current more evenly across drift region 726, thereby reducing the on-state resistance RON of trench MOSFET 700.

Step 1110 may include forming a base region in the epitaxial layer above the drift region. For example, as described above with reference to FIG. 7, base region 728 may be disposed in epitaxial layer 720 above drift region 726. As shown in FIG. 7 for embodiments that include current-spreading region 727, base region 728 may disposed above both drift region 726 and current-spreading region 727. Base region 728 may have an opposite conductivity type relative to drift region 726, current-spreading region 727, and source region 729. For example, in embodiments where trench MOSFET 700 is an n-channel MOSFET, base region 728 may have a p-type doping, which may be referred to as the opposite conductivity type of the n-type doping of drift region 726, current-spreading region 727, and source region 729. In some embodiments, the p-type doping used to form base region 728 may be added, by ion implantation for example, after the growth of epitaxial layer 720.

Step 1112 may include forming a source region in the epitaxial layer above the base region. For example, as described above with reference to FIG. 7, source region 729 may be disposed in epitaxial layer 720 above base region 728. Source region 729 may have the same conductivity type at a higher doping level relative to drift region 726. For example, in embodiments where trench MOSFET 700 is an n-channel MOSFET, source region 729 may have an n-type doping at a higher doping concentration level than drift region 726. The n-type doping for source region 729 may be added during the epitaxial growth process of step 1104 or by additional ion implantation after the epitaxial growth process of step 1104.

Step 1114 may include forming a pillar having an opposite conductivity type relative to the drift region.

As one example described above with reference to FIG. 8, pillar 840 may be formed to extend parallel to trench 730 and through source region 729, base region 728, and current-spreading region 727. In some embodiments, pillar 840 may be formed to extend through current-spreading region 727 to depth less than the maximum depth of current-spreading region 727 as shown in FIG. 8. In other embodiments, pillar 840 may be formed to extend through current-spreading region 727 to a depth equal to or greater than the maximum depth of current-spreading region 727. Pillar 840 may have an opposite conductivity type relative to drift region 726. For example, in embodiments where trench MOSFET 800 is an n-channel MOSFET, pillar 840 may have a heavy p-type doping, which may be referred to as the opposite conductivity type of the n-type doping of drift region 726. In some embodiments, the p-type doping used to form pillar 840 may be added, by ion implantation for example, after the growth of epitaxial layer 720. Pillar 840 may provide shielding for the gate structures (including the portions of dielectric material 734 disposed along first sidewall 731 and second sidewall 732) from electric fields in drift region 726 when a high voltage is applied across the drain and the source of trench MOSFET 800, thereby improving the breakdown voltage (BV) of trench MOSFET 800.

As another example described above with reference to FIG. 10, pillar 1040 may be formed to extend through at least a portion of drift region 726 in a pillar direction parallel to trench 730, the pillar 1040 having an opposite conductivity type relative to drift region 726 to form an angled super-junction structure. In embodiments where trench MOSFET 1000 is an n-channel MOSFET, pillar 1040 may have a heavy p-type doping, which may be referred to as the opposite conductivity type of the n-type doping of drift region 726. In some embodiments, the p-type doping used to form pillar 1040 may be added, by ion implantation for example, after the growth of epitaxial layer 720. The extension of pillar 1040 through drift region 726 may form an angled super-junction structure to improve the breakdown voltage (BV) of trench MOSFET 1000. The respective p-type and n-type doping concentrations of pillar 1040 and drift region 726 may be designed such that the instances of pillar 1040 are charged balanced with the remaining n-type portions of drift region 726. The charge balance of pillars 1040 with the remaining portions of drift region 726 may provide a higher blocking voltage, and thus a higher breakdown voltage (BV), as compared to a fully n-type drift region. In some embodiments, presence of pillars 1040 may allow for a higher n-type doping concentration of drift region 726 for a given breakdown voltage (BV) requirement, thereby providing a lower on-state resistance (RON) for a given die area of trench MOSFET 1000 as a whole.

Step 1116 may include etching a trench through the source region and the base region. For example, as described above with reference to FIG. 7, a dry etch process may be utilized to form trenches 730 extending from the upper surface of epitaxial layer 720 and through source region 729 and base region 728. As shown in FIG. 7 (and similar to trenches 630 shown in FIG. 6), trenches 730 may be etched in the direction of c-axis 721. In other words, trenches 730 may be formed with the same angular offset 723 as the c-axis 721 relative to the surface normal 722 of the upper surface 725 of epitaxial layer 720. Due to this angular offset, each instance of trench 730 may have a rhomboid cross-sectional shape.

The first sidewall 731 of each instance of trench 730 may extend in a direction that is angularly offset from the surface normal 722 of the upper surface 725 of the epitaxial layer 720. Specifically, the first sidewall 731 may extend in the same direction of the c-axis 721 that is angularly offset from the surface normal 722 of the upper surface 725 of the epitaxial layer 720. Further, the second sidewall 732 of each instance of trench 730 may extend parallel to the first sidewall 731 in the direction that is angularly offset from the surface normal 722 of the upper surface 725 of the epitaxial layer 720. Specifically, the second sidewall 732 may extend parallel to the first sidewall 731 in the same direction of the c-axis 721 that is angularly offset from the surface normal 722 of the upper surface 725 of the epitaxial layer 720.

The angled etch may be performed with, for example, a dry etching process. In some embodiments, the ions used to perform the dry etch may be projected toward the surface of epitaxial layer 720 at an angular offset. In other embodiments, the ions used to perform the dry etch may be projected straight downward while a substrate 710 and epitaxial layer 720 are tilted at an oblique angle relative to the direction of ion projection.

In some embodiments, each instance of trench 730 may be arranged such that first sidewall 731 extends along a first non-polar crystal plane of the crystallographic structure of epitaxial layer 720, and that second sidewall extends along a second non-polar crystal plane of the crystallographic structure of epitaxial layer 720. In some embodiments, the first non-polar crystal plane may be a first a-face <112̅0> of the crystallographic structure of epitaxial layer 720, while the second non-polar crystal plane may be a second a-face <112̅0> of the crystallographic structure of epitaxial layer 720. In other embodiments, the first non-polar crystal plane may be a first m-face <11̅00> of the crystallographic structure of epitaxial layer 720, while the second non-polar crystal plane may be a second m-face <11̅00> of the crystallographic structure of epitaxial layer 720. Accordingly, the MOSFET channels formed along first sidewall 731 and second sidewall 732 may benefit from the high electron mobility of the a-faces <112̅0> or the m-faces <11̅00> of epitaxial layer 720. Further, such advantages may be realized in combination with the improved manufacturing cost of forming epitaxial layer 720 with an off-axis growth process.

Step 1118 may include forming a blocking region under the trench. For example, as described above with reference to FIG. 7, blocking region 740 may be formed under gate 736, and specifically under the trench 730 within which gate 736 is disposed. In some embodiments, blocking region 740 may have an opposite conductivity type relative to drift region 726. For example, in embodiments where trench MOSFET 700 is an n-channel MOSFET, blocking region 740 may have a heavy p-type doping, which may be referred to as the opposite conductivity type of the n-type doping of drift region 726, current-spreading region 727, and source region 729. In some embodiments, the p-type doping used to form blocking region 740 may be added, by ion implantation for example, after the growth of epitaxial layer 720. For example, blocking region 740 may be formed after the etching of trench 730, and may utilize the same masking as the dry etch to self-align blocking region 740 under trench 730. Blocking region 740 may provide a shield protecting the above gate structures (including the portions of dielectric material 734 disposed along first sidewall 731 and second sidewall 732) from electric fields in drift region 726 when a high voltage is applied across the drain and the source of trench MOSFET 700, thereby improving the breakdown voltage (BV) of trench MOSFET 700.

Step 1120 may include forming a gate within the trench. For example, as described above with reference to FIG. 7, the gate structures for trench MOSFET 700 may be disposed in trenches 730. In some embodiments, a thin layer of dielectric material 734 may be deposited or grown to line the bottom of trench 730 as well as the first sidewall 731 and second sidewall 732 after trench 730 is etched. The dielectric material 734 may include, for example, silicon dioxide, silicon nitride, or any other material suitable to form a gate dielectric. Gate 736 may then be deposited to fill remaining area within trench 730. Gate 736 may be formed, for example, with polysilicon. Gate 736 may be disposed in a striped pattern extending into the page shown in FIG. 7, and may be coupled via one or more gate contacts and/or gate runners to a gate-pad metal at another location on the semiconductor die on which trench MOSFET 700 is formed. The portions of dielectric material 734 disposed between gate 736 and first sidewall 731, and between gate 736 and second sidewall 732, may serve as a gate dielectric. Channels from source region 729, through base region 728, and to current-spreading region 727 and/or drift region 726, may thus be formed in base region 728 adjacent to first sidewall 731 and adjacent to second sidewall 732. After the polysilicon or other material forming gate 736 is deposited within trench 730, further portions of dielectric material 734 may be deposited above gate 736 to electrically insulate gate 736 from the above source metal 782.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A trench MOSFET, comprising:
a substrate formed with silicon carbide;
an epitaxial layer formed with silicon carbide and disposed on the substrate, the epitaxial layer having a crystallographic structure with a growth direction that is angularly offset from a surface normal of an upper surface of the epitaxial layer;
a drift region formed in a lower portion of the epitaxial layer;
a base region disposed in the epitaxial layer above the drift region;
a source region disposed in the epitaxial layer above the base region;
a trench extending through the source region and the base region, the trench having:
a first sidewall extending in a direction that is angularly offset from the surface normal of the upper surface of the epitaxial layer and along a first non-polar crystal plane of the crystallographic structure of the epitaxial layer; and
a second sidewall extending parallel to the first sidewall in the direction that is angularly offset from the surface normal of the upper surface of the epitaxial layer and along a second non-polar crystal plane of the crystallographic structure of the epitaxial layer; and
a gate formed within the trench.

2. The trench MOSFET of claim 1, wherein the epitaxial layer has a 4H-SiC crystallographic structure.

3. The trench MOSFET of claim 1, wherein the trench has a rhomboid cross-sectional shape.

4. The trench MOSFET of claim 1, wherein:
the first non-polar crystal plane is a first a-face of the crystallographic structure; and
the second non-polar crystal plane is a second a-face of the crystallographic structure.

5. The trench MOSFET of claim 1, wherein:
the first non-polar crystal plane is a first m-face of the crystallographic structure; and
the second non-polar crystal plane is a second m-face of the crystallographic structure.

6. The trench MOSFET of claim 1, further comprising a blocking region formed under the trench, the blocking region having an opposite conductivity type relative to the drift region.

7. The trench MOSFET of claim 1, further comprising a current-spreading region disposed between the drift region and the base region, the current-spreading region having a same conductivity type at a higher doping level relative to the drift region.

8. The trench MOSFET of claim 7, further comprising a pillar extending parallel to the trench and through the source region and the current-spreading region, the pillar having an opposite conductivity type relative to the drift region.

9. The trench MOSFET of claim 1, wherein the trench MOSFET is a super-junction trench MOSFET.

10. The trench MOSFET of claim 9, wherein the super-junction trench MOSFET comprises a pillar extending through at least a portion of the drift region in a pillar direction parallel to the trench, the pillar having an opposite conductivity type relative to the drift region.

11. The trench MOSFET of claim 10, wherein the pillar extends up from the drift region and through the source region.

12. A silicon carbide trench MOSFET, comprising:
a substrate formed with silicon carbide;
an epitaxial layer formed with silicon carbide and disposed on the substrate, the epitaxial layer having a 4H-SiC crystallographic structure with a growth direction that is angularly offset from a surface normal of an upper surface of the epitaxial layer;
a drift region formed in a lower portion of the epitaxial layer;
a base region disposed in the epitaxial layer above the drift region;
a source region disposed in the epitaxial layer above the base region;
a trench extending through the source region and the base region, the trench having:
a first sidewall extending in a direction that is angularly offset from the surface normal of the upper surface of the epitaxial layer and along a first a-face of the 4H-SiC crystallographic structure of the epitaxial layer; and
a second sidewall extending parallel to the first sidewall in the direction that is angularly offset from the surface normal of the upper surface of the epitaxial layer and along a second a-face of the 4H-SiC crystallographic structure of the epitaxial layer; and
a gate formed within the trench.

13. The silicon carbide trench MOSFET of claim 12, wherein the trench has a rhomboid cross-sectional shape.

14. A method for forming a trench MOSFET comprising:
providing a substrate formed with silicon carbide;
growing an epitaxial layer with a crystallographic structure that has a growth direction that is angularly offset from a surface normal of an upper surface of the epitaxial layer;
forming a drift region in a lower portion of the epitaxial layer;
forming a base region in the epitaxial layer above the drift region;
forming a source region in the epitaxial layer above the base region;
etching a trench through the source region and the base region, the trench including:
a first sidewall extending in a direction that is angularly offset from the surface normal of the upper surface of the epitaxial layer and along a first non-polar crystal plane of the crystallographic structure of the epitaxial layer; and
a second sidewall extending parallel to the first sidewall in the direction that is angularly offset from the surface normal of the upper surface of the epitaxial layer and along a second non-polar crystal plane of the crystallographic structure of the epitaxial layer; and
forming a gate within the trench.

15. The method of claim 14, wherein:
the first non-polar crystal plane is a first a-face of the crystallographic structure; and
the second non-polar crystal plane is a second a-face of the crystallographic structure.

16. The method of claim 14, further comprising forming a blocking region under the trench, the blocking region having an opposite conductivity type relative to the drift region.

17. The method of claim 14, further comprising forming a current-spreading region between the drift region and the base region, the current-spreading region having a same conductivity type at a higher doping level relative to the drift region.

18. The method of claim 17, further comprising forming a pillar through the source region and the current-spreading region and parallel to the trench, the pillar having an opposite conductivity type relative to the drift region.

19. The method of claim 14, further comprising forming a pillar extending through at least a portion of the drift region in a pillar direction parallel to the trench, the pillar having an opposite conductivity type relative to the drift region to form an angled super-junction structure.

20. The method of claim 19, wherein the pillar extends up from the drift region and through the source region.
